(19) United States
(12) Patent Application Publication
(10) Pub. No.: US 2020/0043913 A1
(43) Pub. Date: Feb. 6, 2020

(54) STRUCTURE INTEGRATING FIELD-EFFECT TRANSISTOR WITH HETEROJUNCTION BIPOLAR TRANSISTOR

(71) Applicant: Chan Shin WU, Taipei City (TW)

(72) Inventor: Chan Shin WU, Taipei City (TW)

(21) Appl. No.: 16/341,433

(22) PCT Filed: Oct. 18, 2016
(86) PCT No.: PCT/CN2016/102344

§ 371 Date: Apr. 11, 2019

(51) Int. Cl. H01L 27/06; H01L 29/737; H01L 29/47

(52) U.S. Cl. CPC H01L 27/0623; H01L 29/47; H01L 29/7371

(57) ABSTRACT

A structure for integrating a field-effect transistor (FET) and a heterojunction bipolar transistor (HBT) is provided. The structure includes: a substrate; a first epitaxial structure located on the substrate, having a part of the HBT; and a second epitaxial structure located on the first epitaxial structure, having a part of the FET.

### FIELD OF THE INVENTION

The invention relates to an epitaxial structure capable of integrating a field-effect transistor (FET) and a heterojunction bipolar transistor (HBT), and more particularly to a structure for vertically integrating an FET and an HBT.

### DESCRIPTION OF THE PRIOR ART

Developing a heterojunction bipolar transistor (HBT) has become one crucial technology in many applications, particularly in a power amplifier used for a wireless communication system. A pseudomorphic high electron mobility transistor (pHEMT) is a type of field-effect transistor (FET) formed on gallium arsenide (GaAs). To enhance the performance of an HBT used for a power amplifier, an integrated device, referred to as a bipolar high electron mobility transistor (BiHEMT), with switch and control circuit functions formed by combining an HBT and a pHEMT is available.

A typical BiHEMT device includes an HBT layer grown on a pHEMT layer. To expose the pHEMT layer, the entire HBT layer needs to be etched away. However, due to a large height difference between surfaces of the pHEMT layer and the HBT layer, the manufacturing process is made significantly more complex. For example, in a high-frequency application, the length of a gate electrode in the pHEMT layer needs to be as low as 0.15 um, whereas the thickness of the HBT layer may be as high as 2.5 um. This large aspect ratio causes manufacturing difficulties, which affect the levelness and likely cause proximity effects such that the pHEMT device cannot be placed near the HBT device. The layout and degree of freedom in circuit design are therefore restricted, while the dimension of a chip and costs are also increased. Therefore, there is a need for a novel BiHEMT for solving the above issues.

### SUMMARY OF THE INVENTION

To solve the above issues, the present invention conceives of placing a field-effect transistor (FET), e.g., a pseudomorphic high electron mobility transistor (pHEMT), having a smaller critical dimension and being harder to manufacture on a heterojunction bipolar transistor (HBT). The critical dimension of an HBT is at minimum approximately 1 um to 3 um, which is much larger than a pHEMT having a dimension of approximately 0.15 um to 0.5 um. If the HBT can be grown before the FET is manufactured in an epitaxy growth process, the FET can be vertically integrated on the top of the HBT, providing advantages of a convenient manufacturing process and optimized performance. When an FET (pHEMT) is placed on an HBT in an epitaxial structure, the control on the critical dimension (0.15 um to 0.5 um) during the manufacturing process of the FET (pHEMT) becomes relatively easy, and the manufacturing and control for the HBT in a dimension of 1 um to 3 um is also easy because the structure of the FET (pHEMT) is very thin.

In a conventional structure, an FET is located at a lower layer whereas an HBT is located at an upper layer, and so modifying the HBT to the lower layer and the FET to the upper layer can be challenging. In a conventional HBT epitaxial structure, an emitter contact layer at the uppermost layer is epitaxy InGaAs, which does not match with lattices of various epitaxial layers based on GaAs, such as GaAs, AlGaAs and InGaP. Therefore, severe lattice mismatch can be resulted if an FET structure based on GaAs is directly placed on top of an emitter contact layer InGaAs serving as an HBT, and interface dislocation can be further resulted, which further leads to interface defects.

Further, to achieve high performance and low resistance, a conventional HBT structure usually includes a gradient InGaAs layer with mismatching lattices. This layer is not a monocrystalline structure but is a polycrystalline layer. Both electrical performance and crystallization are degraded if an HEMT (or pHEMT) is directly grown on this polycrystalline layer, likely leading to deep traps of electrons, shredded dislocation, leakage current and unstable current, thus failing the specification requirements of a switch and control circuit device.

In one aspect regarding the manufacturing process, the present invention conceives of vertically integrating an FET on top of an HBT so as to significantly reduce the critical dimensions as well as complexities in placement positions during the manufacturing process for both the FET and HBT. In another aspect, the present invention further conceives of having lattices of a material used for the top contact layer of the HBT match lattices of a base of the FET. The present invention further includes other aspects including material optimization, which achieves low series connection and low contact emitter resistance for the HBT device, and at the same time achieves a pHEMT switch device having a low leakage current. Thus, the HBT becomes a high-performance power amplifier while the FET (HEMT or pHEMT) also satisfies specification requirements of a switch and control circuit device.

The present invention further includes other embodiments for solving other issues. Further, details of the above embodiments are disclosed in the Detailed Description of the Embodiments below.

### BRIEF DESCRIPTION OF THE DRAWINGS

The invention will be described with below figures.

FIG. 1a and FIG. 1b are schematic diagrams of an integrated structure of an FET and an HBT according to an embodiment of the present invention;

FIG. 2 is a schematic diagram of an integrated structure of an FET and an HBT according to another embodiment of the present invention;

FIG. 3 is a schematic diagram of an integrated structure of an FET and an HBT according to yet another embodiment of the present invention;

FIG. 4 is a schematic diagram of an integrated structure of an FET and an HBT according to yet another embodiment of the present invention; and

FIG. 5 is a schematic diagram of an integrated structure of an FET having a metal contact pattern and an HBT according to another embodiment of the present invention.

### DETAILED DESCRIPTION OF THE EMBODIMENTS

Preferred embodiments of the present invention are given with the accompanying drawings below. In the drawings, similar elements are represented by the same element denotations. It should be noted that, to clearly illustrate the present invention, the elements are not drawn to true scales of actual objects. Further, to focus on the contents of the present invention, known principles, components, associated materials and associated processing technologies are omitted.

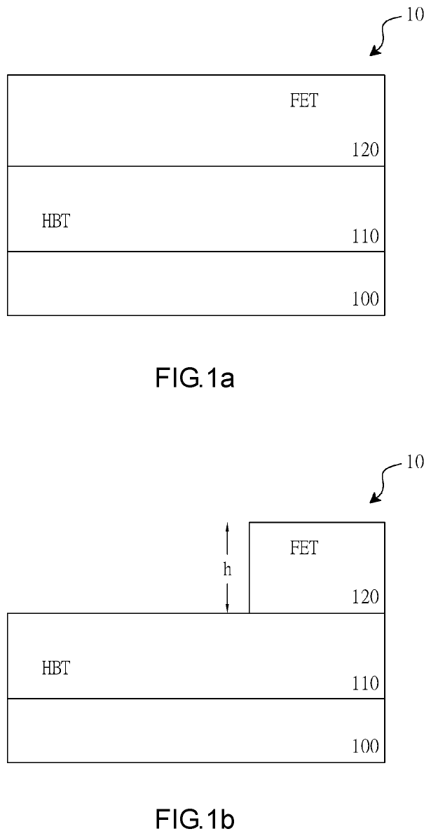

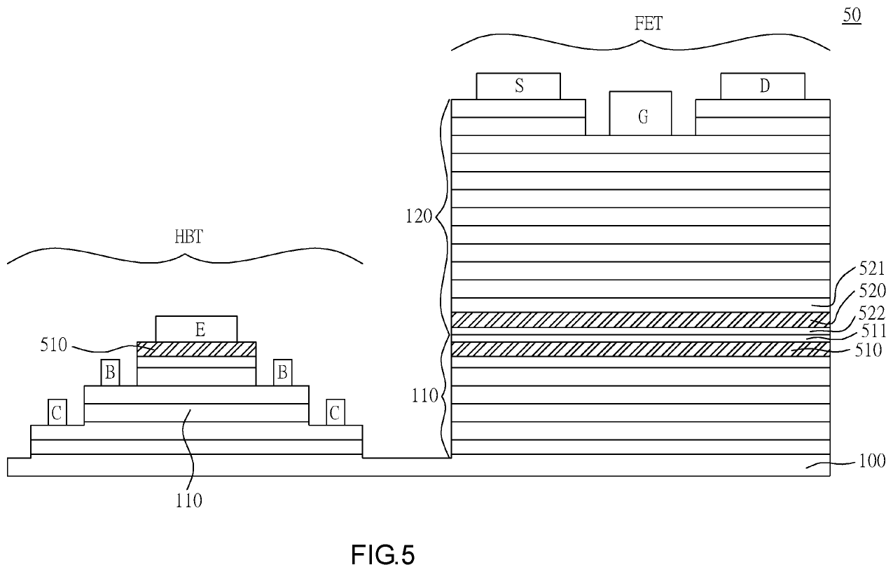

As shown in FIG. 1a and FIG. 1b, according to some embodiments, the present invention provides a structure 10 for integrating a field-effect transistor (FET) and a heterojunction bipolar transistor (HBT). The structure 10 includes: a substrate 100, a first epitaxial structure 110 located on the substrate 100, having a part of the HBT; and a second epitaxial structure 120 located on the first epitaxial structure 110, having a part of the FET. The FET may be formed by various types of epitaxial layers, and includes pseudomorphic high electron mobility transistor (pHEMT), high electron mobility transistor (HEMT), metal semiconductor field-effect transistor (MESFET), metal-oxide semiconductor field-effect transistor (MOSFET), or any other appropriate structures. The HBT and the FET may be combined to form an integrated power amplifier device having switch and control circuit functions, e.g., a bipolar high electron mobility transistor (BiHEMT). In the structure 10, the substrate 100 is usually a GaAs substrate, or may be any other material on which an HBT and an FET can be appropriately manufactured. The first epitaxial structure 110 and the second epitaxial structure 120 formed on the substrate 100 may be formed by known technologies, including chemical vapor deposition (CVD), metal-organic chemical vapor deposition (MOCVD) and molecular beam epitaxy (MBE), etc. Referring to FIG. 1a and FIG. 1b, steps for manufacturing the structure 10 may include: forming, on the substrate 100, the first epitaxial structure 110 including the layers needed for forming an HBT; forming, on the first epitaxial structure 110, the second epitaxial structure 120 including the layers needed for forming an FET; and etching away a part of the second epitaxial structure 120 to expose the first epitaxial structure 110 underneath. Next, using a conventional lithography technology, pattern lines and metal contacts needed by the HBT are completed on the basis of the structure 10. According to the structure 10, the manufacturing process for an HBT device is relatively simple. More specifically, because the upper-layer FET does not demand a strict requirement on the thickness, a difference h between a surface of the second epitaxial structure 120 and an exposed surface of the first epitaxial structure 110 is low in comparison, with the aspect ratio significantly reduced. After the structure needed by the HBT device is completed, an appropriate mask is used to cover the HBT device, and pattern lines and metal contacts needed by the FET are similarly completed through a conventional lithography technology on the second epitaxial structure 120. Compared to a conventional structure in which an HBT is on an FET, in the structure 10 disclosed by the present invention, the FET is on the HBT and a smaller manufacturing aspect ratio is provided, such that the FET can be close to the HBT, increasing the degree of freedom in the integrated circuit design and decreasing the dimension of the chip. It is thus known that, vertically integrating the FET on the HBT provides advantages of a convenient manufacturing process and optimized performance. That is to say, the manufacturing process is made more flexible—considering actual manufacturing capabilities, a pHEMT can be manufactured before manufacturing an HBT, an HBT can be manufactured before manufacturing a pHEMT, or a pHEMT and an HBT can be simultaneously manufactured. FIG. 5 shows a schematic diagram of a structure 50 vertically integrating an FET having a metal contact pattern and an HBT according to the present invention. Referring to FIG. 5, the structure 50 includes a substrate 100, a first epitaxial structure 110 and a second epitaxial structure 120. A part of the second epitaxial structure 120 is provided with an FET structure including a source S, a gate G and a drain D, which are formed through patterning and metal deposition and are stacked on the first epitaxial structure 110. Another part of the second epitaxial structure 120 is removed to expose a part of the first epitaxial structure 110. This exposed part of the first epitaxial structure 110 is provided with an HBT structure including base B, a collector C and an emitter E which are formed through patterning and metal deposition.

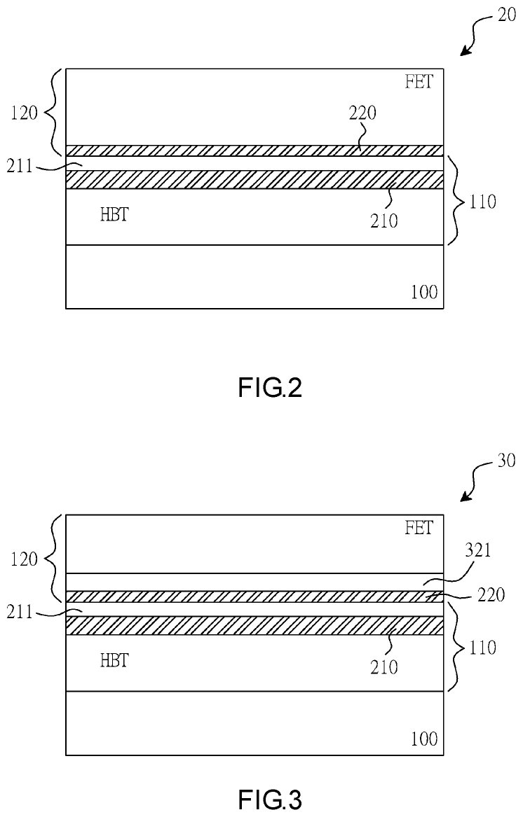

Referring to FIG. 2, according to other embodiments of the present invention, the present invention provides a similar structure 20 in which the second epitaxial structure 120 is located on the first epitaxial structure 110. A contact layer 210 of an HBT included in the first epitaxial structure 110 is locate at the top of the HBT. The second epitaxial structure 120 includes a doped separation layer 220, which is closest to the contact layer 210 and is used for electrically separating the FET and the HBT. Depending on requirements, other layers, e.g., an etching stop layer 211 or an undoped buffer layer, can be provided between the contact layer 210 and the doped separation layer 220. To reinforce the structure, the present invention further conceives of matching lattices of the contact layer 210 and the doped separation layer 220. In a preferred lattice matching situation, a difference between a lattice constant of the contact layer 210 and a lattice constant of the doped separation layer 220 is less than or equal to the lattice constant of the contact layer 210 by 0.15%. According to this value, an appropriate material may be selected. The contact layer may be, for example but not limited to, Ge, In_{0.5}Ga_{0.5}P, and AlₓGa₁₋ₓAs, where x=0 to 1. The doped separation layer may be, for example but not limited to, Ge, In_{0.5}Ga_{0.5}P, and AlₓGa₁₋ₓAs, where x=0 to 1. Layers of other functions may be provided between the contact layer 210 and the doped separation layer 220, and are preferably layers having lattices matching those of the doped separation layer 220 and the contact layer 210. For example, the etching stop layer 211 in FIG. 2 may also be, for example but not limited to, Ge, In_{0.5}Ga_{0.5}P, and AlₓGa₁₋ₓAs, where x=0 to 1.

Referring to FIG. 2, in addition to improving lattice dislocation and reinforcing the structure, the present invention further conceives of achieving requirements of outstanding electrical characteristics. Thus, energy gaps, Schottky energy barriers 4B and doping concentrations of various materials are further studied. According to some other embodiments, a structure 20 similar to that in FIG. 2 in which the second epitaxial structure 120 located on the first epitaxial layer 110 is provided. It is discovered by the present invention that the contact layer 210 having an energy gap less than or equal to 0.7 eV provides preferred lower ohmic resistance. Further, according to some other embodiments, a structure 20 similar to that in FIG. 2 in which the second epitaxial structure 120 located on the first epitaxial layer 110 is provided. It is further discovered by the present invention that a contact layer having a Schottky energy barrier ϕB less than or equal to 0.65 eV yields a more noticeable tunneling effect. According to the various materials with matching lattices, a more appropriate material can be selected for manufacturing the contact layer. For example, in the various embodiments with matching lattices, using Ge for a contact layer is a better selection than using GaAs. Although using GaAs as a contact layer of an HBT provides matching lattices, GaAs has an energy gap more than 0.7 eV and a Schottky energy barrier ϕB more than 0.65 eV. As a result, issues of excessively large series resistance and contact resistance may be caused if GaAs is used as the contact layer of an HBT.

Definitions and measurements of the abovementioned lattice constant, energy gap and Schottky energy barrier ϕB can be referred from conventional technologies, e.g., “Physics of Semiconductor Devices” of S. M. Sze, Second Edition, Table-3 “Measured Schottky Barrier Heights” on p. 291, Appendix F “Lattice Constants” on p. 848, and Appendix H “Properties of Ge, Si, GaAs at 300K” on p. 850.

Referring to FIG. 2, according to some other embodiments of the present invention, a structure 20 similar to that in FIG. 2 in which the second epitaxial structure 120 located on the first epitaxial layer 110 is provided. It is further discovered by the present invention that the doping concentration (having a unit of cm⁻³ throughout the disclosure) of the contact layer 210 is within a range between 3×10¹⁹ and 1×10²⁰, preferably within a range between 5×10¹⁹ and 1×10²⁰, which is capable of keeping the series resistance and contact resistance at very small values. Meanwhile, the thickness of the contact layer 210 is appropriately increased so as to prevent the metal of the emitter ohmic contact subsequently manufactured on the contact layer 210 from diffusing into an area of the emitter layer underneath. Further, also referring to FIG. 2, according to some other embodiments of the present invention, to provide the upper-layer FET and the lower-layer HBT with better electrical isolation, the present invention further discovers that, making the electrical characteristics of the contact layer 210 to be opposite those of the doped separation layer 220, preferably making the doping quality (doping count #/cm²) of the contact layer 210 to be even to that of the doped separation layer 220, can effectively prevent parasitic capacitance. In practice, a difference between the doping quality of the contact layer 210 and the doping quality of the doped separation layer 220 can be controlled within 10% of an average value of the two. In these embodiments, taking the NPN-type for example, when the contact layer is n⁺Ge, the doped separation layer may be, for example but not limited to, p-GaAs or p⁺GaAs. When the contact layer is Ge, a doping concentration of 10²⁰ cm⁻³ is achievable. Refer to “Ultra-doped n-type germanium thin films for sensing in the mid-infrared” of Slawomir Prucnal et al., published in Scientific Reports, Jun. 10, 2016. In the above publication, it is disclosed that n-Ge grown by δ-doped MBE can reach 10²⁰ cm⁻³, and thus the contact resistance can be kept within a low range of 10⁻⁸ Ω-cm².

In some embodiments, when the etching stop layer 211 is present between the contact layer 210 and the doped separation layer 220, the etching stop layer 211 uses the same material having lattices matching those of the contact layer 210 and the doped separation layer 220; however, the etching stop layer 211 is not doped.

Referring to FIG. 3 as well as Table-1 and Table-2, according to some other embodiments of the present invention, a structure 30 in which the second epitaxial structure 120 is located on the first epitaxial structure 110 is provided. The first epitaxial structure 110 includes a contact layer 210 of an HBT, wherein the contact layer 210 is located at the top of the HBT. The second epitaxial structure 120 includes a doped separation layer 220 closest to the contact layer 210. In addition to the doped separation layer 220, the second epitaxial structure 120 further includes an undoped layer 321, which is located on the doped separation layer 220 at the bottom of the FET. The present invention discovers that the undoped layer 321 effectively prevents the FET from generating a leakage current. The undoped layer may be single-layer or multi-layer, and may include a super-lattice layer. The overall thickness of the undoped layer is preferably between 5,000 Å and 10,000 Å. For example, when Ge⁺ is used as the contact layer 210, the undoped layer 321 may be a super-lattice layer alternately formed by undoped GaAs, undoped AlGaAs, undoped GaAs and undoped AlGaAs, or a combination of the above.

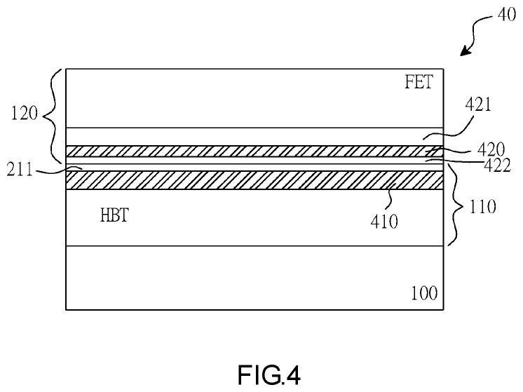

Referring to FIG. 4 and Table-2, according to some other embodiments, a structure 40 in which the second epitaxial structure 120 located on the first epitaxial structure 110 is provided. The first epitaxial structure 110 includes a contact layer 410 of an HBT, wherein the contact layer 410 is located at the top of the HBT. The second epitaxial layer 120 includes a doped separation layer 420 closest to the contact layer 410. The contact layer 410 and the doped separation layer 420 have opposite electrical characteristics. In addition to the doped separation layer 420, the second epitaxial structure 120 further includes an undoped buffer layer 422 located between the contact layer 410 and the doped separation layer 420. The undoped buffer layer 422, different from a common etching stop layer 211, is located on the etching stop layer 211 in this embodiment. The present invention discovers that, the undoped buffer layer 422 effectively prevents the FET from generating a leakage current. For example, when Ge⁺ is used as a contact layer 410 and P⁺GaAs is used as a doped separation layer, the undoped buffer layer 422 may be undoped AlGaAs, and have a thickness between 1,000 Å and 2,000 Å.

By using a conventional lithography technology, pattern lines and metal contacts needed by the HBT/FET can be completed on the basis of the structure 20 or 30 in FIG. 2 or FIG. 3, as a structure 50 shown in FIG. 5. The structure 50 similarly includes a contact layer 510, a doped separation layer 520, an etching stop layer 511 and an undoped layer 521, an undoped buffer layer 522 similar to those described above.

Table 1 shows details of the layers of a structure integrating an FET and an HBT according to a first preferred embodiment of the present invention.

TABLE 1
Description on materials of epitaxial
layers according to first embodiment

| Second | S/D ohmic contact layer | | n⁺-InGaAs (or n⁺-GaAs) |
|---|---|---|---|
| epitaxial | Etching stop layer | | i-In_{0.5}Ga_{0.5}P (or i-AlAs) |
| structure | Barrier layer | | i-AlGaAs |
| | δ-doped layer | | n⁺-AlGaAs |
| | Separation layer | | i-AlGaAs |
| | Channel layer | | i-InGaAs |
| | Separation layer | | i-AlGaAs |
| | δ-dope layer | | n⁺-AlGaAs |
| | Undoped | Undoped barrier layer | i-AlGaAs |
| | layer | Undoped buffer super- | i-AlGaAs/GaAs |
| | | lattice barrier | |
| | | layer (optional) | |
| | | Undoped buffer layer | i-AlGaAs |

| | | |
|---|---|---|
| | Doped separation layer | p-GaAs |
| First | Etching stop layer | i-In_{0.5}Ga_{0.5}P |
| epitaxial | Contact layer | n⁺Ge |
| structure | Emitter transmission layer | n⁺-GaAs |
| | Emitter transmission layer | n-GaAs |
| | Wide-band emitter layer | n-In_{0.5}Ga_{0.5}P |
| | Base layer | p⁺-GaAs |
| | First collector layer | n⁻-GaAs |
| | Second collector layer | n-GaAs |
| | Secondary collector layer | n⁺-GaAs |
| | Buffer layer | i-GaAs |
| Substrate | Insulation substrate | SI GaAs |

As shown in Table 1, the thicknesses of the contact layer (n⁺Ge) and the emitter transmission layer (n⁺-GaAs, n-GaAs) can be appropriately increased, so as to prevent the metal of the emitter ohmic contact subsequently manufactured on the contact layer from diffusing into the wide-band emitter layer (n-In_{0.5}Ga_{0.5}P) underneath.

Table 2 shows details of the layers of a structure integrating an FET and an HBT according to a second preferred embodiment of the present invention.

TABLE 2
Description on materials of epitaxial layers according to second embodiment

| | | | | Thickness | Doping |
|---|---|---|---|---|---|
| | | | | (Å) | (cm⁻³) |
| Second | S/D ohmic contact layer | | n⁺-InGaAs (or n⁺- GaAs) | 310-320 | 4-5 × 10¹⁸ |
| epitaxial | Second etching stop layer | | i-In_{0.5}Ga_{0.5}P(or i-AlAs) | 50-60 | Undoped |
| structure | Second Schottky barrier layer | | n-InGaAs (or n⁺-GaAs) | 150-160 | 2-3 × 10¹⁷ |
| | (depletion mode) | | | | |
| | First etching stop layer | | i-In_{0.5}Ga_{0.5}P(or i-AlAs) | 50 | Undoped |
| | 1b Schottky barrier layer-1b | | i-GaAs | 40 | Undoped |
| | (enhancement mode) | | | | |
| | 1a Schottky barrier layer-1a | | n-Al_{0.24}Ga_{0.76}As | 250-260 | 1-2 × 10¹⁷ |
| | (enhancement mode) | | | | |
| | δ-dope layer | | n⁺-Al_{0.24}Ga_{0.76}As | 45-55 | 5 × 10¹⁸ |
| | Separation layer | | i-Al_{0.24}Ga_{0.76}As | 25-30 | Undoped |
| | Channel layer | | i-In_{0.20}Ga_{0.80}As | 120 | Undoped |
| | Separation layer | | i-Al_{0.24}Ga_{0.76}As | 30 | Undoped |
| | δ-doped layer | | n⁺-Al_{0.24}Ga_{0.76}As | 30-40 | 3-3.5 × 10¹⁸ |
| | Undoped | Undoped barrier | i-Al_{0.24}Ga_{0.76}As | 150 | Undoped |
| | layer | layer | | | |
| | | Undoped buffer | i-Al_{0.24}Ga_{0.76}As/GaAs | 20 × 200/15 | Undoped |
| | | super-lattice | | | |
| | | barrier layer | | | |
| | | Undoped buffer | i-Al_{0.24}Ga_{0.76}As | 1000 | Undoped |
| | | layer | | | |

| | | | | |
|---|---|---|---|---|
| | Doped separation layer | p⁺-GaAs | 1000 | >1 × 10¹⁹ |
| | Undoped buffer layer | i-Al_{0.24}Ga_{0.76}As | 1000 | Undoped |
| First | Etching stop layer | i-In_{0.5}Ga_{0.5}P(or i-AlAs) | 100 | 3 × 10¹⁷ |
| epitaxial | Contact layer | n⁺Ge | 600-800 | >1 × 10¹⁹ |
| structure | Emitter transmission layer | n⁺-GaAs | 1000-1200 | 5 × 10¹⁸ |
| | Wide-band emitter layer | n-In_{0.5}Ga_{0.5}P | 400-500 | 3-4 × 10¹⁷ |
| | Base layer | p⁺-GaAs | 800-1000 | 3-4 × 10¹⁹ |
| | First collector layer | n⁻-GaAs | 5000-6000 | 1-2 × 10¹⁶ |
| | Second collector layer | n-GaAs | 4000-5000 | 3-4 × 10¹⁶ |
| | Secondary collector layer | n⁺-GaAs | 5000-6000 | 5 × 10¹⁸ |
| | Undoped buffer layer | i-GaAs | 0-2000 | Undoped |
| Substrate | Insulation substrate | SI GaAs | 675 ± 25 um | Undoped |

As shown in Table-2, the thicknesses of the contact layer (n⁺Ge, 600 Å to 800 Å) and the emitter transmission layer (n⁺-GaAs, 1,000 Å to 1,200 Å) have been appropriately increased, thus preventing the metal of the emitter ohmic contact subsequently manufactured on the contact layer from diffusing into the wide-band emitter layer (n-In_{0.5}Ga_{0.5}P) underneath.

While the invention has been described by way of the preferred embodiments above, it is to be understood that the invention includes many other embodiments covered by the claims. Without departing from the spirit disclosed by the present invention, equivalent changes and modifications made are to be encompassed within the scope of the appended claims.

### LIST OF REFERENCE NUMERALS

10 structure
100 substrate
110 first epitaxial structure
120 second epitaxial structure
20 structure
210 contact layer
211 etching stop layer
220 doped buffer layer
30 structure
321 undoped layer
40 structure
410 contact layer
420 doped separation layer
421 undoped layer
422 undoped buffer layer
50 structure
510 contact layer
511 etching stop layer
520 doped separation layer
521 undoped layer
522 undoped buffer layer

1. A structure for integrating a field-effect transistor (FET) and a heterojunction bipolar transistor (HBT), comprising:
a substrate;
a first epitaxial structure, located on the substrate, comprising a part of the HBT; and
a second epitaxial structure, located on the first epitaxial structure, comprising a part of the FET;
wherein, the first epitaxial structure comprises a contact layer of the HBT, and the contact layer is located at the top of the HBT; and the second epitaxial structure comprises a doped separation layer, which is closest to the contact layer and is for electrically separating the FET and the HBT.

2. The structure for integrating an FET and an HBT according to claim 1, wherein a difference between a lattice constant of the contact layer and a lattice constant of the doped separation layer is less than or equal to the lattice constant of the contact layer by 0.15%.

3. The structure for integrating an FET and an HBT according to claim 1, wherein the contact layer has an energy gap less than or equal to 0.7 eV.

4. The structure for integrating an FET and an HBT according to claim 1, wherein the contact layer has a Schottky energy barrier ϕ_{B} less than or equal to 0.65 eV.

5. The structure for integrating an FET and an HBT according to claim 1, wherein the contact layer has a doping concentration within a range between 3×10¹⁹ and 1×10²⁰.

6. The structure for integrating an FET and an HBT according to claim 1, wherein the contact layer is Ge.

7. The structure for integrating an FET and an HBT according to claim 6, wherein the doped separation layer is gallium arsenide (GaAs).

8. The structure for integrating an FET and an HBT according to claim 1, wherein an electrical characteristic of the contact layer is opposite to an electrical characteristic of the doped separation layer.

9. The structure for integrating an FET and an HBT according to claim 8, wherein a difference between a doping quality of the contact layer and a doping quality of the doped separation layer is within 10% of an average value of the both.

10. The structure for integrating an FET and an HBT according to claim 8, wherein the second epitaxial structure comprises an undoped layer located at the bottom of the FET and on the doped separation layer, and the undoped layer is single-layer or multi-layer and has a thickness between 5,000 Å and 10,000 Å.

11. The structure for integrating an FET and an HBT according to claim 8, wherein the second epitaxial structure comprises an undoped buffer layer located between the doped separation layer and the contact layer, and the undoped buffer layer has a thickness between 1,000 Å and 2,000 Å.
